(19) United States
(12) Patent Application Publication
(10) Pub. No.: US 2025/0309147 A1
(43) Pub. Date: Oct. 2, 2025

(54) SEMICONDUCTOR DEVICE, INSPECTION METHOD, AND SEMICONDUCTOR CHIP

(71) Applicants: ROHM Co., Ltd., Kyoto (JP); LAPIS Semiconductor Co., Ltd., Yokohama (JP)

(72) Inventors: Junichi IKEDA, Yokohama (JP); Takumi TAKAHASHI, Yokohama (JP)

(73) Assignees: ROHM Co., Ltd., Kyoto (JP); LAPIS Semiconductor Co., Ltd., Yokohama (JP)

(21) Appl. No.: 19/090,438

(22) Filed: Mar. 26, 2025

(30) Foreign Application Priority Data
Mar. 27, 2024 (JP) 2024-052436

(51) Int. Cl. H01L 23/58; H01L 21/66; H01L 23/544

(52) U.S. Cl. CPC H01L 23/585; H01L 22/14; H01L 23/544; H01L 2223/54426

(57) ABSTRACT

A semiconductor device includes a first semiconductor chip and a second semiconductor chip connected to each other. The first semiconductor chip includes a first alignment mark and a second alignment mark composed of conductors electrically isolated from each other, and a first terminal and a second terminal electrically connected to the first alignment mark and the second alignment mark. The second semiconductor chip includes a guard ring including an annular conductor provided along an outer edge of the second semiconductor chip, and a third alignment mark and a fourth alignment mark composed of conductors electrically connected to the guard ring. The first semiconductor chip and the second semiconductor chip are connected such that the first alignment mark and the third alignment mark overlap with each other, and the second alignment mark and the fourth alignment mark overlap with each other.

### CROSS-REFERENCE TO RELATED APPLICATION

This application claims the priority benefit of Japan application serial no. 2024-052436, filed on Mar. 27, 2024. The entirety of the above-mentioned patent application is hereby incorporated by reference herein and made a part of this specification.

### BACKGROUND

### Technical Field

The disclosed technique relates to a semiconductor device, an inspection method, and a semiconductor chip.

### Related Art

As a technique related to mounting of semiconductor chips using alignment marks, the following technique is known. For example, Patent Document 1 (Japanese Patent Application Laid-Open No. 2002-111148) describes a circuit board on which a semiconductor chip having electrode pads provided on one main surface is flip-chip mounted. The circuit board includes an insulating substrate, a circuit pattern formed on one main surface of the insulating substrate, metal bumps for bonding formed on the circuit pattern to bond the electrode pads and the circuit pattern, and alignment marks formed on one main surface of the insulating substrate and used for alignment when flip-chip mounting the semiconductor chip to the circuit board.

As a technique related to inspection of electrical connection between the semiconductor chips, the following technique is known. For example, Patent Document 2 (Japanese Patent Application Laid-Open No. 2004-20550) describes an inspection circuit for inspecting electrical connection between semiconductor chips of a chip-on-chip (COC) configuration in which one or more semiconductor chips are bonded and mounted on a semiconductor chip serving as a base.

In a semiconductor device with a multi-chip configuration including multiple semiconductor chips, inspection is performed on the electrical connection between the semiconductor chips. As an inspection method, it is conceivable to operate an internal circuit included in any of the semiconductor chips, but this method requires a relatively long inspection time.

### SUMMARY

A semiconductor device according to the disclosed technique includes a first semiconductor chip and a second semiconductor chip connected to the first semiconductor chip. The first semiconductor chip includes: a first alignment mark composed of a conductor; a second alignment mark composed of a conductor electrically isolated from the first alignment mark; a first terminal electrically connected to the first alignment mark; and a second terminal electrically connected to the second alignment mark. The second semiconductor chip includes: a guard ring including an annular conductor provided along an outer edge of the second semiconductor chip; a third alignment mark composed of a conductor electrically connected to the guard ring; and a fourth alignment mark composed of a conductor electrically connected to the guard ring. The first semiconductor chip and the second semiconductor chip are connected such that the first alignment mark and the third alignment mark overlap with each other, and the second alignment mark and the fourth alignment mark overlap with each other.

An inspection method according to the disclosed technique is an inspection method of the semiconductor device described above and includes: measuring electrical properties indicating an electrical connection state between the first terminal and the second terminal.

A semiconductor chip according to the disclosed technique includes: a first alignment mark composed of a conductor; a second alignment mark composed of a conductor electrically isolated from the first alignment mark; a first terminal electrically connected to the first alignment mark; and a second terminal electrically connected to the second alignment mark.

Another semiconductor chip according to the disclosed technique includes: a guard ring including an annular conductor provided along an outer edge of the semiconductor chip; a third alignment mark composed of a conductor electrically connected to the guard ring; and a fourth alignment mark composed of a conductor electrically connected to the guard ring.

### BRIEF DESCRIPTION OF THE DRAWINGS

FIG. 1 is a perspective view showing an example of a configuration of a semiconductor device according to an embodiment of the disclosed technique.

FIG. 2 is a plan view of a first semiconductor chip according to an embodiment of the disclosed technique viewed from the side of a bonding surface bonded with a second semiconductor chip.

FIG. 3 is a plan view of the second semiconductor chip according to an embodiment of the disclosed technique viewed from the side of a bonding surface bonded with the first semiconductor chip.

FIG. 4 is a cross-sectional view taken along a line 4-4 in FIG. 3.

FIG. 5 is a plan see-through view of the semiconductor device in a state in which the first semiconductor chip and the second semiconductor chip according to an embodiment of the disclosed technique are bonded.

FIG. 6 is a view schematically showing a conductive path formed by bonding the first semiconductor chip and the second semiconductor chip according to an embodiment of the disclosed technique.

### DESCRIPTION OF THE EMBODIMENTS

Embodiments of the disclosed technique enable simple inspection of an electrical connection state between semiconductor chips in a semiconductor device with a multi-chip configuration including multiple semiconductor chips.

Hereinafter, embodiments of the disclosed technique will be described with reference to the drawings. In each drawing, substantially same or equivalent constituent elements or parts will be labeled with the same reference signs.

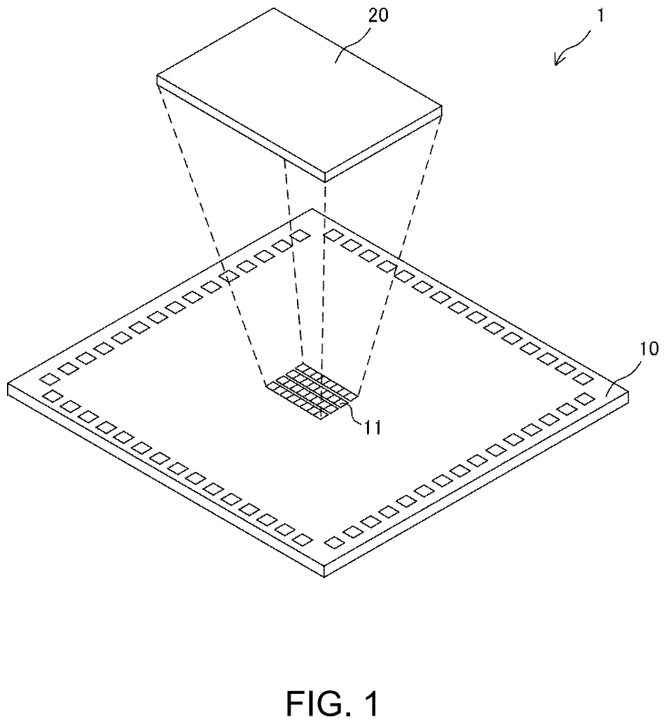

FIG. 1 is a perspective view showing an example of a configuration of a semiconductor device 1 according to an embodiment of the disclosed technique. The semiconductor device 1 has a multi-chip configuration including a first semiconductor chip 10 and a second semiconductor chip 20. The first semiconductor chip 10 is, for example, a custom chip and has a functional part for realizing a specific function according to the use. The second semiconductor chip 20 is, for example, a general-purpose core chip and has a general-purpose functional part such as a CPU and a memory. The uses and functions of the first semiconductor chip 10 and the second semiconductor chip 20 are not particularly limited.

The first semiconductor chip 10 and the second semiconductor chip 20 each have multiple connection terminals arranged in a grid pattern on the surface of a semiconductor substrate. FIG. 1 shows multiple connection terminals 11 provided on the first semiconductor chip 10. The first semiconductor chip 10 and the second semiconductor chip 20 are electrically and mechanically connected to each other by bonding the connection terminals together. The connection terminals may be composed of Cu, for example, and the bonding between the connection terminals may be Cu—Cu bonding.

An area of the first semiconductor chip 10 is larger than an area of the second semiconductor chip 20, and the second semiconductor chip 20 is stacked on the first semiconductor chip 10. After the second semiconductor chip 20 is connected to the first semiconductor chip 10, access to the second semiconductor chip 20 is possible only via the first semiconductor chip 10.

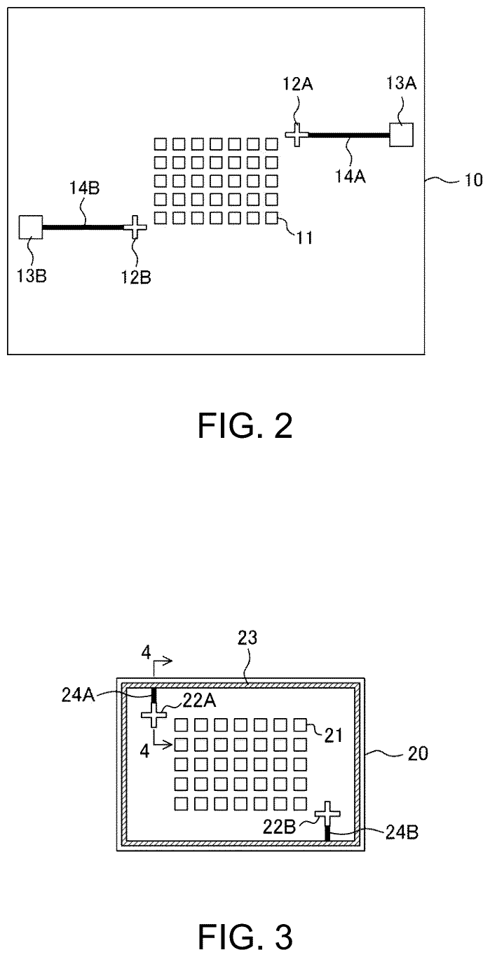

FIG. 2 is a plan view of the first semiconductor chip 10 viewed from the side of a bonding surface bonded with the second semiconductor chip 20. The first semiconductor chip 10 includes multiple connection terminals 11, alignment marks 12A and 12B, and measurement terminals 13A and 13B.

The multiple connection terminals 11 are terminals used for connection with the second semiconductor chip 20. The multiple connection terminals 11 are provided at a central part of the first semiconductor chip 10. Each of the multiple connection terminals 11 is composed of a conductor such as Cu.

The alignment marks 12A and 12B are marks used for alignment between the first semiconductor chip 10 and the second semiconductor chip 20. The alignment marks 12A and 12B are provided on an outer side of the multiple connection terminals 11. The positions of the alignment marks 12A and 12B correspond to the positions of alignment marks 22A and 22B (refer to FIG. 3) of the second semiconductor chip 20, which will be described later. The alignment marks 12A and 12B are composed of the same material as the connection terminals 11, and are composed of, for example, a conductor such as Cu. The alignment marks 12A and 12B are electrically isolated from each other.

The alignment marks 12A and 12B may have a characteristic shape different from the connection terminals 11 to enhance recognition accuracy by image recognition. FIG. 2 illustrates the alignment marks 12A and 12B having a cross-shaped pattern as an example. However, the disclosed technique is not limited to this configuration, and the pattern of the alignment marks 12A and 12B may be defined in any manner. The alignment mark 12A is an example of a “first alignment mark” in the disclosed technique, and the alignment mark 12B is an example of a “second alignment mark” in the disclosed technique.

Measurement terminals 13A and 13B are electrode pads used for inspecting the electrical connection between the first semiconductor chip 10 and the second semiconductor chip 20. The measurement terminal 13A is electrically connected to the alignment mark 12A via a wiring 14A, and the measurement terminal 13B is electrically connected to the alignment mark 12B via a wiring 14B. The measurement terminals 13A and 13B are composed of a conductor such as Al. The measurement terminals 13A and 13B are disposed, for example, in the vicinity of an outer edge of the first semiconductor chip 10. The first semiconductor chip 10 may also have multiple terminals other than the measurement terminals 13A and 13B provided along the outer edge thereof, as shown in FIG. 1. The measurement terminal 13A is an example of a “first terminal” in the disclosed technique, and the measurement terminal 13B is an example of a “second terminal” in the disclosed technique.

FIG. 3 is a plan view of the second semiconductor chip 20 viewed from the side of a bonding surface bonded with the first semiconductor chip 10. The second semiconductor chip 20 includes multiple connection terminals 21, alignment marks 22A and 22B, and a guard ring 23.

The multiple connection terminals 21 are terminals used for connection with the first semiconductor chip 10 and correspond to the multiple connection terminals 11 provided on the first semiconductor chip 10. The multiple connection terminals 21 are provided at a central part of the second semiconductor chip 20. Each of the multiple connection terminals 21 is composed of a conductor such as Cu.

The alignment marks 22A and 22B are marks used for alignment between the first semiconductor chip 10 and the second semiconductor chip 20. The alignment marks 22A and 22B are provided on an outer side of the multiple connection terminals 21. The alignment marks 22A and 22B may be disposed in the vicinity of two corner parts that form a diagonal with each other on the second semiconductor chip 20. The positions of the alignment marks 22A and 22B correspond to the positions of the alignment marks 12A and 12B (refer to FIG. 2) provided on the first semiconductor chip 10. The alignment marks 22A and 22B are composed of the same material as the connection terminals 21, and are composed of, for example, a conductor such as Cu.

The alignment mark 22A is electrically connected to the guard ring 23 via a wiring 24A, and the alignment mark 22B is electrically connected to the guard ring 23 via a wiring 24B. The alignment marks 22A and 22B may be respectively provided in the vicinity of the guard ring 23. For example, the distance between the alignment marks 22A and 22B and the guard ring 23 may be 10% or less of the length of one side of the second semiconductor chip 20 in a rectangular shape. Accordingly, the disposing region of the wirings 24A and 24B can be reduced.

The alignment marks 22A and 22B may have a characteristic shape different from the connection terminals 21 to enhance recognition accuracy in image recognition. FIG. 3 illustrates the alignment marks 22A and 22B having a cross-shaped pattern as an example. However, the disclosed technique is not limited to this configuration, and the pattern of the alignment marks 22A and 22B may be defined in any manner. The alignment mark 22A is an example of a “third alignment mark” in the disclosed technique, and the alignment mark 22B is an example of a “fourth alignment mark” in the disclosed technique.

The guard ring 23 is composed of an annular conductor provided along an outer edge of the second semiconductor chip 20. The region on an inner side of the guard ring 23 is taken as a device region where devices that realize the inherent function of the second semiconductor chip 20 are formed. For example, in the device region, circuits composed of elements such as transistors, resistive elements, capacitors, and wirings are formed. The second semiconductor chip 20 is individualized by cutting a wafer along scribe lines. With the guard ring 23 surrounding an outer periphery of the device region, it becomes possible to suppress the risk of chipping in which cracks that may occur during individualization of the second semiconductor chip 20 extend to the device region. As described above, the alignment marks 22A and 22B are each electrically connected to the guard ring 23. Since the guard ring 23 is composed of an annular conductor, the alignment mark 22A and the alignment mark 22B are electrically connected to each other via the guard ring 23.

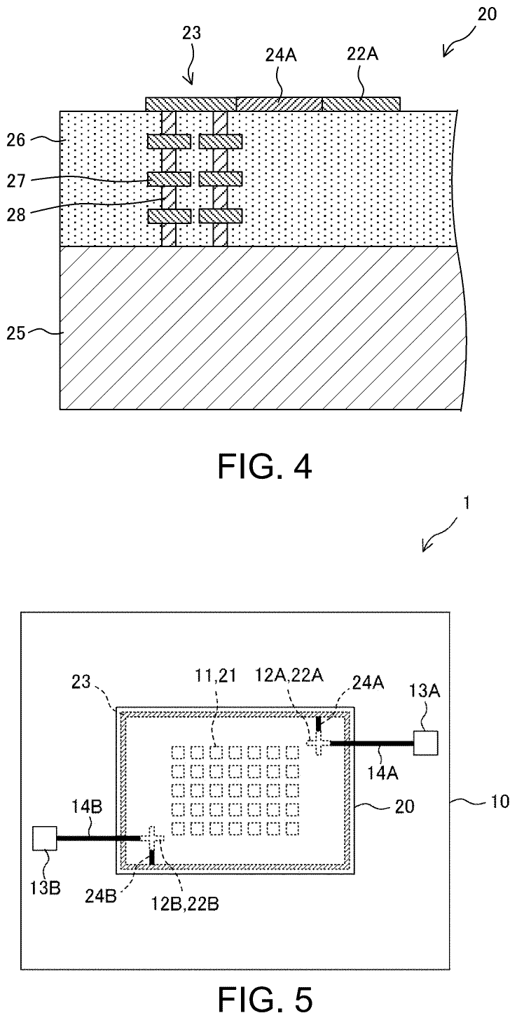

FIG. 4 is a cross-sectional view taken along a line 4-4 in FIG. 3. The second semiconductor chip 20 includes a semiconductor substrate 25 such as a silicon substrate, and an insulating layer 26 provided on the semiconductor substrate 25. The guard ring 23 includes multiple layers of conductive films 27 provided inside the insulating layer 26. Each layer of conductive film 27 is connected to the adjacent layer of conductive film 27 via a via 28. The alignment mark 22A and the wiring 24A are provided on the surface of the insulating layer 26. Among the conductive films 27 constituting the guard ring 23, the alignment mark 22A is connected via the wiring 24A to the topmost layer of conductive film 27 which is provided on the surface of the insulating layer 26. The same also applies to the alignment mark 22B and the wiring 24B.

FIG. 5 is a plan see-through view of the semiconductor device 1 in a state in which the first semiconductor chip 10 and the second semiconductor chip 20 are bonded. The first semiconductor chip 10 and the second semiconductor chip 20 are connected such that the alignment marks 12A and 22A overlap with each other, and the alignment marks 12B and 22B overlap with each other. Accordingly, alignment between the first semiconductor chip 10 and the second semiconductor chip 20 is performed, and corresponding connection terminals of the multiple connection terminals 11 and the multiple connection terminals 21 are bonded to each other.

The alignment mark 12A provided on the first semiconductor chip 10 and the alignment mark 22A provided on the second semiconductor chip 20 are bonded to each other, for example, by Cu—Cu bonding. Similarly, the alignment mark 12B provided on the first semiconductor chip 10 and the alignment mark 22B provided on the second semiconductor chip 20 are bonded to each other, for example, by Cu—Cu bonding. In the state in which the first semiconductor chip 10 and the second semiconductor chip 20 are bonded, the measurement terminals 13A and 13B are exposed without being covered by the second semiconductor chip 20.

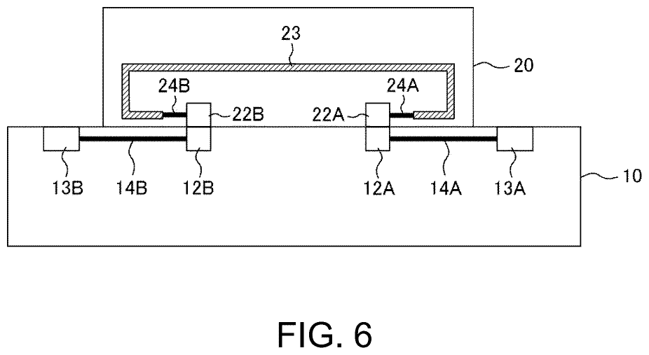

FIG. 6 is a view schematically showing a conductive path formed by bonding the first semiconductor chip 10 and the second semiconductor chip 20. In the case where the electrical connection between the alignment mark 12A and the alignment mark 22A and the electrical connection between the alignment mark 12B and the alignment mark 22B are properly formed, the measurement terminal 13A is electrically connected to the measurement terminal 13B via the wiring 14A, the alignment mark 12A, the alignment mark 22A, the wiring 24A, the guard ring 23, the wiring 24B, the alignment mark 22B, the alignment mark 12B, and the wiring 14B. Accordingly, by confirming the electrical connection state between the measurement terminal 13A and the measurement terminal 13B, it is possible to learn about the electrical connection state between the alignment mark 12A and the alignment mark 22A, and the electrical connection state between the alignment mark 12B and the alignment mark 22B.

In the first semiconductor chip 10, the surfaces of the alignment marks 12A and 12B and the connection terminals 11 are planarized by chemical mechanical polishing (CMP), and the surface heights are uniform. Similarly, in the second semiconductor chip 20, the surfaces of the alignment marks 22A and 22B and the connection terminals 21 are planarized by CMP, and the surface heights are uniform. The electrical connection between the connection terminals 11 provided on the first semiconductor chip 10 and the connection terminals 21 provided on the second semiconductor chip 20 is formed by Cu—Cu bonding, which is the same as the electrical connection between the alignment marks. Accordingly, in the case where the electrical connection between the alignment mark 12A and the alignment mark 22A, and the electrical connection between the alignment mark 12B and the alignment mark 22B are properly formed, it can be considered that the electrical connection between the connection terminals 11 and the connection terminals 21 is also properly formed. Thus, by confirming the electrical connection state between the measurement terminal 13A and the measurement terminal 13B, it is possible to simply perform inspection on the electrical connection state between the connection terminals 11 and the connection terminals 21 (i.e., the electrical connection state between the first semiconductor chip 10 and the second semiconductor chip 20).

The inspection method of the electrical connection state between the first semiconductor chip 10 and the second semiconductor chip 20 according to the embodiment of the disclosed technique includes measuring electrical properties indicating the electrical connection state between the measurement terminal 13A and the measurement terminal 13B. For example, a voltage of the measurement terminal 13B upon applying a predetermined voltage (e.g., 1 V) to the measurement terminal 13A may be measured. In that case, in the case where the measured value of the voltage of the measurement terminal 13B is substantially equal to the level of the voltage applied to the measurement terminal 13A, it can be determined that the electrical connection state via the connection terminals 11 and 21 between the first semiconductor chip 10 and the second semiconductor chip 20 is good. In contrast, in the case where the measured value of the voltage of the measurement terminal 13B differs from the level of the voltage applied to the measurement terminal 13A, it can be determined that the electrical connection state via the connection terminals 11 and 21 between the first semiconductor chip 10 and the second semiconductor chip 20 is defective.

The electrical properties indicating the electrical connection state between the measurement terminal 13A and the measurement terminal 13B may also be an electrical resistance between the measurement terminal 13A and the measurement terminal 13B. In that case, in the case where the electrical resistance between the measurement terminal 13A and the measurement terminal 13B is less than a predetermined value, it can be determined that the state of electrical connection via the connection terminals 11 and 21 between the first semiconductor chip 10 and the second semiconductor chip 20 is good. In contrast, in the case where the electrical resistance between the measurement terminal 13A and the measurement terminal 13B is equal to or greater than the predetermined value, it can be determined that the state of electrical connection via the connection terminals 11 and 21 between the first semiconductor chip 10 and the second semiconductor chip 20 is defective. The measurement of the electrical properties indicating the electrical connection state between the measurement terminal 13A and the measurement terminal 13B may be performed, for example, by bringing probes (not shown) respectively into contact with the measurement terminal 13A and the measurement terminal 13B.

As described above, according to the semiconductor device 1 of the embodiment of the disclosed technique, it is possible to simply inspect the electrical connection state between the first semiconductor chip 10 and the second semiconductor chip 20. Herein, in the second semiconductor chip 20, consider the case where the electrical connection between the alignment marks 22A and 22B is performed by a wiring provided at the second semiconductor chip 20. Since the alignment marks 22A and 22B are disposed at positions away from each other, the length of the wiring for electrically connecting the alignment marks 22A and 22B becomes relatively long. Accordingly, in the case where the electrical connection between the alignment marks 22A and 22B is performed by a wiring provided at the second semiconductor chip 20, it is required to ensure a relatively wide region for disposing the wiring in the second semiconductor chip 20. In the case where it is difficult to ensure a relatively wide region for disposing the wiring, it becomes necessary to increase the size of the second semiconductor chip 20. In contrast, according to the semiconductor device 1 of the embodiment of the disclosed technique, since the electrical connection between the alignment marks 22A and 22B is performed by the guard ring 23, it is not required to ensure a relatively wide region for disposing the wiring described above in the second semiconductor chip 20.

The following notes are further disclosed in relation to the above embodiments.

### (Note 1)

A semiconductor device including a first semiconductor chip and a second semiconductor chip connected to the first semiconductor chip, where
the first semiconductor chip includes:
a first alignment mark composed of a conductor;
a second alignment mark composed of a conductor electrically isolated from the first alignment mark;
a first terminal electrically connected to the first alignment mark; and a second terminal electrically connected to the second alignment mark,
the second semiconductor chip includes:
a guard ring including an annular conductor provided along an outer edge of the second semiconductor chip;
a third alignment mark composed of a conductor electrically connected to the guard ring; and
a fourth alignment mark composed of a conductor electrically connected to the guard ring, and
the first semiconductor chip and the second semiconductor chip are connected such that the first alignment mark and the third alignment mark overlap with each other, and the second alignment mark and the fourth alignment mark overlap with each other.

### (Note 2)

The semiconductor device according to Note 1, where
the third alignment mark and the fourth alignment mark are respectively provided in the vicinity of the guard ring.

### (Note 3)

The semiconductor device according to Note 1 or 2, where
the first semiconductor chip is larger than the second semiconductor chip, and in a state in which the first semiconductor chip and the second semiconductor chip are bonded, the first terminal and the second terminal are exposed.

### (Note 4)

The semiconductor device according to any one of Notes 1 to 3, where
the first semiconductor chip and the second semiconductor chip respectively include connection terminals for connecting to each other, and
the first alignment mark, the second alignment mark, the third alignment mark, and the fourth alignment mark each have a shape different from that of the connection terminals.

### (Note 5)

An inspection method, which is an inspection method of the semiconductor device according to any one of Notes 1 to 4, the inspection method including:
measuring electrical properties indicating an electrical connection state between the first terminal and the second terminal.

### (Note 6)

A semiconductor chip including:
a first alignment mark composed of a conductor;
a second alignment mark composed of a conductor electrically isolated from the first alignment mark;
a first terminal electrically connected to the first alignment mark; and a second terminal electrically connected to the second alignment mark.

### (Note 7)

A semiconductor chip including:
a guard ring including an annular conductor provided along an outer edge of the semiconductor chip;
a third alignment mark composed of a conductor electrically connected to the guard ring; and a fourth alignment mark composed of a conductor electrically connected to the guard ring.

What is claimed is:

1. A semiconductor device comprising a first semiconductor chip and a second semiconductor chip connected to the first semiconductor chip, wherein
the first semiconductor chip comprises:
a first alignment mark composed of a conductor;
a second alignment mark composed of a conductor electrically isolated from the first alignment mark;
a first terminal electrically connected to the first alignment mark; and
a second terminal electrically connected to the second alignment mark,
the second semiconductor chip comprises:
a guard ring comprising an annular conductor provided along an outer edge of the second semiconductor chip;
a third alignment mark composed of a conductor electrically connected to the guard ring; and
a fourth alignment mark composed of a conductor electrically connected to the guard ring, and
the first semiconductor chip and the second semiconductor chip are connected such that the first alignment mark and the third alignment mark overlap with each other, and the second alignment mark and the fourth alignment mark overlap with each other.

2. The semiconductor device according to claim 1, wherein
the third alignment mark and the fourth alignment mark are respectively provided in the vicinity of the guard ring.

3. The semiconductor device according to claim 1, wherein
the first semiconductor chip is larger than the second semiconductor chip, and in a state in which the first semiconductor chip and the second semiconductor chip are bonded, the first terminal and the second terminal are exposed.

4. The semiconductor device according to claim 1, wherein
the first semiconductor chip and the second semiconductor chip respectively comprise connection terminals for connecting to each other, and
the first alignment mark, the second alignment mark, the third alignment mark, and the fourth alignment mark each have a shape different from that of the connection terminals.

5. An inspection method, which is an inspection method of the semiconductor device according to claim 1, the inspection method comprising:
measuring electrical properties indicating an electrical connection state between the first terminal and the second terminal.

6. A semiconductor chip comprising:
a first alignment mark composed of a conductor;
a second alignment mark composed of a conductor electrically isolated from the first alignment mark;
a first terminal electrically connected to the first alignment mark; and
a second terminal electrically connected to the second alignment mark.

7. The semiconductor chip according to claim 6, wherein the first alignment mark overlaps with a third alignment mark, the third alignment mark being composed of a conductor and electrically connected to a guard ring comprising an annular conductor provided along an outer edge of a different semiconductor chip.

8. The semiconductor chip according to claim 7, wherein the second alignment mark overlaps with a fourth alignment mark, the fourth alignment mark being composed of a conductor and electrically connected to the guard ring.
